(19) United States
(12) Patent Application Publication
(10) Pub. No.: US 2012/0292590 A1
(43) Pub. Date: Nov. 22, 2012

(54) OPTICAL COMPONENT

(75) Inventors: Anthony John BENNETT, Cambridge (GB); Andrew James SHIELDS, Cambridge (GB); Joanna Krystyna SKIBA-SZYMANSKA, Cambridge (GB)

(73) Assignee: Kabushiki Kaisha Toshiba, Tokyo (JP)

(21) Appl. No.: 13/475,423

(22) Filed: May 18, 2012

(30) Foreign Application Priority Data
May 20, 2011 (GB) 1108565.1

(51) Int. Cl. H01L 29/66; H01L 21/04

(52) U.S. Cl. 257/10; 438/20; 257/E29.168; 257/E21.089

(57) ABSTRACT

An optical component comprising an emitter and a solid reflector, said reflector having a convex outer surface, said emitter being located within the solid reflector, the emitter being configured to emit radiation via an electric dipole transition, the dipole having a dipole axis being orientated at an angle of 45 degrees or less to the surface normal at the apex of the reflector.

### FIELD

Embodiments of the present invention described generally herein relate to optical components.

### BACKGROUND

In the field of quantum cryptography, quantum imaging and quantum computing there is a need to produce photons from single quantum emitters. Such photons can be produced in a regulated manner, as the single quantum state can only emit one photon at a time. After a photon is emitted the state must be refilled with more charges before it can emit again. The low numbers of photon produced increases the need for such sources to be highly efficient with each photon being directed in a certain direction and efficiently collected by conventional optics, such as a lens or an optic fibre.

Many of the most promising solid state emitters are based within high refractive index materials, such as Indium Arsenide quantum dots in Gallium Arsenide (refractive index, n ˜3.5) and colour centers in Diamond (n ˜2.4). In such materials light can only escape from the material to air or a vacuum when it strikes the material/air interface at an angle less than sin(1/n) to the normal, angles outside this range being totally internally reflected. In GaAs this limits the number of photons that can be collected from a planar surface with a dot beneath it to 2%, and into a typical lens with numerical aperture 0.5 this value is ˜0.5%.

### BRIEF DESCRIPTION OF THE DRAWINGS

The present invention will now be described with reference to the following preferred non-limiting embodiments in which:

FIG. 1 is a schematic of a component in accordance with an embodiment of the present invention;

FIG. 2(a) is a schematic showing the angles over which light emitted by a dipole is reflected by a paraboloid. FIG. 2(b) schematically shows a optical dipole oriented perpendicular to the central axis and FIG. 2(c) schematically shows the optical dipole oriented parallel to the central axis in accordance with an embodiment of the present invention;

FIGS. 3(a), (b) and (c) show three components in accordance with embodiments of the present invention with differing paraboloid shapes;

FIG. 4 shows variations on the shape of the reflector, FIG. 4(a) shows a paraboloid with a flattened base; FIG. 4(b) shows a reflector having a paraboloidal section with straight wall sections at the base and top; FIG. 4(c) shows a cross-section of a rotationally symmetric paraboloid and FIG. 4(d) shows a cross-section of an elliptical paraboloid;

FIGS. 5 (a) and (b) show components in accordance with embodiments of the present invention with different configurations of the quantum dot, in undoped semiconductor.

FIG. 6(a) shows a quantum dot form in an plea-I-an structure configured for electrical excitation, the quantum dot has a dipole which is perpendicular to the growth direction of the layers, FIG. 6(b) shows a quantum dot in a p-i-n structure where the quantum dot is formed using a sub monolayer technique such that it's dipole is parallel to the growth direction,

FIG. 7 shows stages in wafers bonding, FIG. 7(a) shows samples to being prepared for bonding, FIG. 7(b) shows bonding of the samples of FIG. 7(a), FIG. 7(c) shows preparation of the samples of FIG. 7(b) for further bonding and FIG. 7(d) shows further samples be bonded to the samples FIG. 7(b);

FIG. 8 shows the holder used to mount the sample during polishing and lithography; and

FIG. 9 shows the stages of lithography to pattern the paraboloid of the reflector, FIG. 9(a) shows the exposing of the grey scale resist, FIG. 9(b) shows the developing of the resist to produce the paraboloid shape, FIGS. 9(c) and 9(d) show etching through the resist to transfer the paraboloid shape to the semiconductor and FIG. 9(e) shows the patterned reflector.

### DETAILED DESCRIPTION

In an embodiment, an optical component is provided comprising an emitter and a solid reflector, said reflector having a convex outer surface, said emitter being located within the solid reflector, the emitter being configured to emit radiation via an electric dipole transition, the dipole having a dipole axis being orientated at an angle of 45 degrees or less to the surface normal at the apex of the reflector.

In a further embodiment, the dipole axis is oriented at an angle of 30 degrees or less to the surface normal at the apex of the reflector.

In an embodiment, the apex is the point of the convex outer surface which is closest to the emitter.

In an embodiment, the emitter is a quantum emitter which is configured to emit single photons which are temporally separated or pairs of photons.

In an embodiment said reflector has a paraboloid-shaped outer surface and a central axis extending from the apex of the paraboloid along the normal to the surface at this apex.

In an embodiment, the emitter is provided at the focus of the paraboloid.

In an embodiment, said dipole is positioned such that at least 50% of its emission is reflected by the outer surface in a direction parallel to the surface normal at the apex of the reflector.

In one embodiment the outer surface of said solid reflector has a shape defined by the equation in cylindrical polar coordinates:

z=A(x²+y²)^{α}

where z is the distance along the axis of rotational symmetry, r=(x²+y²) is the distance from the axis of rotational symmetry and α is a number between 0.95 and 1.05, and A is a parameter.

In an embodiment, A is 400000 m⁻¹. In a further embodiment, the paraboloid has a true paraboloidal shape, where α=1.

In a further embodiment, at least a part of the curved surface reflector is a paraboloid that has a focal point within the solid reflector and the emitter is located at said focal point.

The quantum dot in the reflector may be optically excited and the component comprises a laser configured to optically excite said emitter.

In a yet further embodiment, the emitter is electrically excited and further comprises electrical contacts configured to electrically excite said emitter.

In one embodiment, the emitter comprises a quantum dot and said solid reflector comprises a semiconductor based material. The solid reflector may comprise GaAs or GaAs based material. In a further embodiment, the solid reflector comprises diamond and said emitter comprises a defect or colour centre in said diamond.

The reflector may be provided within a surrounding material which has a lower refractive index than the reflector. In one embodiment, the surrounding material is air.

In a further embodiment, the reflector is coated with metal.

In a further embodiment, a method of forming an optical component, the method comprising:
forming a quantum dot provided within a solid structure, said quantum dot having a dipole axis;
patterning said solid structure to have a shape which is substantially a paraboloid,
the solid structure having a central axis extending from the apex of the paraboloid and through the centre of the paraboloid, said patterning positioning said solid structure such that the dipole axis of said quantum dot forms an angle of 45 degrees or less with the central axis of the reflector, the reflector having a refractive index which is higher than any surrounding medium.

Patterning said structure may comprise providing a grey-scale resist to define said paraboloid shape.

The dipole of the quantum dot may be arranged parallel to the plane of the layers of the semiconductor structure. In such cases, said grey-scale resist can be provided on the edge of the wafer to define the curved surface in the semiconductor structure.

In a further embodiment, the structure is patterned using a focussed ion beam to define the convex outer surface.

In one embodiment, said quantum dot is formed using a self-assembled technique. In a further embodiment, the quantum dot is formed using alternating layers of GaAs and InAs, the thickness of the GaAs and InAs layers each being less than a few monolayers. Such a technique forms what is called a “sub-monolayer” quantum dot with a dipole formed parallel to the growth direction of the layers.

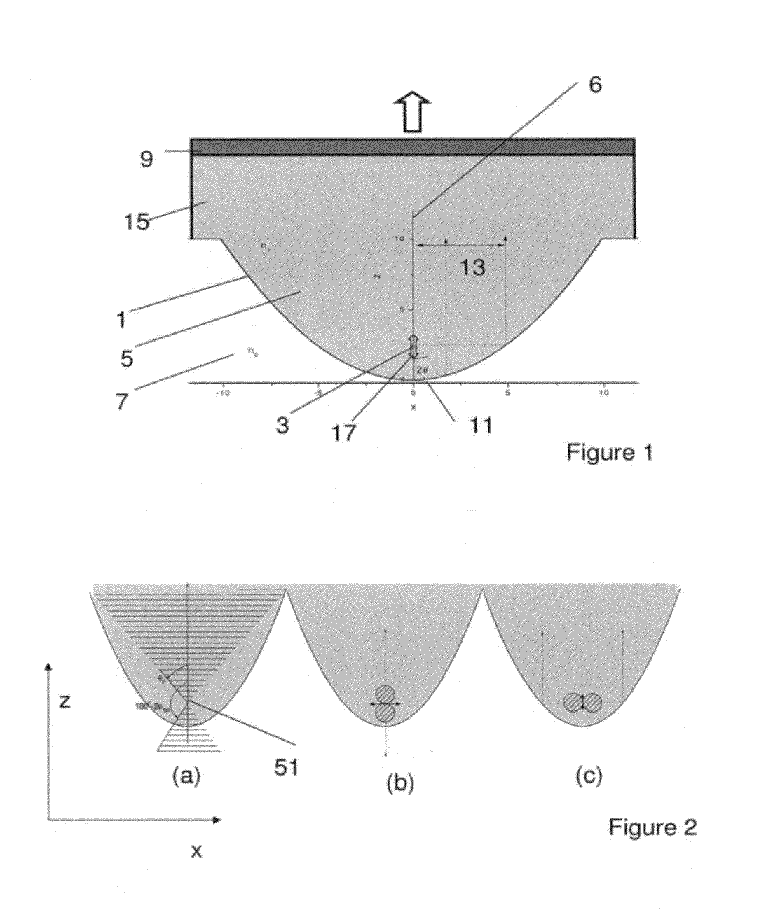

FIG. 1 is a schematic showing a component in accordance with an embodiment of the invention.

FIG. 1 is a schematic of the component in accordance with an embodiment of the present invention. The component comprises a reflector 1 which in this particular example is formed into the shape of a paraboloid. FIG. 1 shows a section through the paraboloid. The paraboloid has a focal point 3 which is located along its central axis of symmetry 6. The reflector 1 comprises a material with a first refractive index n₁ while its surrounding medium 7 comprises material having a second refractive index n₀. The first refractive index is higher than the second refractive index.

The quantum dot is provided at the focal point 3. The quantum dot has a dipole axis 17 which in this embodiment is aligned along the central axis 6.

In the example of FIG. 1, the paraboloid reflector 1 is formed on top of a substrate 15. Overlying and on top of substrate 15 is anti-reflective coating 9. Radiation emitted by the quantum dot located at focal point 3 will be reflected by 1 and exit through the substrate and through the anti-reflective coating 9.

FIG. 2a shows a reflector having a paraboloid-shaped outer surface. In FIG. 2a, the shape is paraboloid. A paraboloid is a 3-dimensional surface obtained by the rotation of a parabola (a 2-D line following the relationship z=Ar^{2α}) about the z-axis. The paraboloid is described by the equation

z=Ar^{2α}=A(x²+y²)^{α}

This surface has a property that a point source located at the focal point 51 of the paraboloid (which has a location x=0, y=0 and z=1/(4A)) will have emission reflected into the z-direction.

In the structure shown in FIG. 1, reflection of photons by the surface of the paraboloid which is an interface between the high index material 5 with index n₁ and the low index material 7 with index n₀. Snell's law of optics states that a ray of light striking such an interface from the high index side at an angle of θ₁ to the normal of the surface may be refracted to exit into material 7 at an angle of θ₀. Where

n₀ sin θ₀=n₁ sin θ₁

This will be the case for θ_{TIR}=θ₁<sin⁻¹(n₀/n₁). For angles greater than this (θ_{TIR}<θ₁) total internal reflection will occur.

For an interface between GaAs and air, θ_{TIR} is 16.6 degrees. In the geometry of FIG. 1 this corresponds to light emitted at an angle of less than 180°−2θ_{TIR}, to the vertical z-direction=146.8 degrees.

For light emitted in the upwards direction without reflection from the curved surface, some can be collected directly by a lens (not shown) above the sample. However, very little of the light emitted by such a dipole is actually emitted in this direction, for simplicity it is assumed to be a negligible flux. Rather, the geometry of the paraboloid of FIG. 1 provides a more relevant limit on the angles that can be collected.

FIG. 2a show that only light emitted at an angle to the z-direction which is greater than θ_{P} will be reflected by the surface of the paraboloid. This precise angle is set by the height of the paraboloid and the parameter A, and can be optimised.

An optical dipole such as that provided by a quantum dot cannot emit light along the direction of its axis. In fact the total emission varies as sin³φ, where φ is the angle between the direction of light emission and the dipole axis. The emission occurs symmetrically around the axis of the dipole, resulting in the emission probability having a “doughnut shape”, the cross section of which is shown schematically in FIG. 2b and c.

In the case of FIG. 2b the dipole is aligned along the x-direction and the emission is likely to occur in the z-y plane, where it will not be efficiently reflected by the paraboloid of FIG. 1 and hence subsequently collected. This geometry is the easiest to achieve with a quantum dot in a semiconductor, as these dots naturally form with their dipole in the growth plane, and thus processing can be carried out on the flat surface of the sample which is easier.

In the component of FIG. 2c, where the dipole is aligned along the direction of the z-axis (axis of symmetry) of the paraboloid of FIG. 1. In this case the fraction of light that is reflected upwards from the paraboloid surface is given by

$$η = \frac{{\int }_{{θ}_{p}}^{180 ° - 2 {θ}_{TIR}} {sin}^{3} θ \cdot d θ}{{\int }_{0}^{180 °} {sin}^{3} θ \cdot d θ}$$

Which for an optimal reflector with a small value of θ_{P} is 98.3% in GaAs surrounded by air.

Light reflected by the paraboloid of FIG. 1 will then travel upwards along the z-direction. It shall have zero flux at its centre, with a maximum value at a radius of ½A. The electric field vector shall point radially in the emitted beam.

In an embodiment, this mode shape can be efficiently collected by optics in the far field along the z-direction, provided the optimum parameters of A and paraboloid height are chosen.

If the diameter of the mode is too small at the sample (i.e. diameter of the mode=1/A is smaller than the wavelength in the material) then divergence of the beam will occur before it can be collected. In an embodiment, to aid collection of the radiation, A<5×10⁶ m⁻¹ for a dot in GaAs and A<3.5×10⁶ m⁻¹ for an emitter in diamond. Alternatively, for a low value of A and low height, the angle θₚ, will be large and a smaller fraction of light can be collected.

In an embodiment, the “height” of the paraboloid is greater than the distance between the emitter and the origin in FIG. 1 (which is ¼A). Using the limit on A from the above embodiment this equates to a height of 50 nm in GaAs and 29 nm in diamond. In an embodiment, the reflector has as great a height as possible, which will be limited only by fabrication issues. In both materials maximum heights of several 10s of microns are achievable.

In a further embodiment, the paraboloid is encased in an inert low-refractive index surrounding material (not shown) (such as Silicon oxide, Silicon Nitride or a polymer resist) to aid in physical manipulation of the device or to minimise oxidation of exposed GaAs surface. In this case the angle of total internal reflection may be increased.

Table 1 is a table giving combinations of refection material and surrounding material with theoretical collection efficiencies for the preferred embodiments, assuming that Op is small:

| | n₁ | n₀ | θ_{TIR} | η |
|---|---|---|---|---|
| GaAs in air | 3.5 | 1 | 16.6° | 98% |
| GaAs in SiO2 | 3.5 | 1.5 | 25.4° | 90% |
| Diamond in Air | 2.4 | 1 | 24.6° | 91% |

In a further embodiment a layer of reflecting material is provided on the outer surface of the reflector such a layer may be gold (which has a high reflectivity), or silver (which has a low absorption rate) to enhance the reflection of light upwards. This would also act to passivate the surface against oxidation.

In an embodiment the quantum dot is at least 100 nm from the surface of the paraboloid. This consideration is met by the previously quoted values of A<5×10⁶ m⁻¹ for a dot in GaAs and A<3.5×10⁶ m⁻¹ for an emitter in diamond.

In an embodiment a GaAs reflector is used. However other materials could be used for the reflector. For example, it is possible to form the device on an InP substrate, which is suited for emission at longer wavelengths.

The above embodiment uses a paraboloid light collimator to increase the efficiency of collection to nearly 100% using a robust and simple design. This is based upon the same optical principle as that found in car-headlights, satellite dishes and radio-telescope dishes: namely that a paraboloid (the 3D surface formed by rotation of a parabola around its axis) will reflect all incoming light along its axis, to its focal point. Similarly, a single source located at this focal point will have all radiation reflected by the surface collimated into beam with parallel rays.

By orienting the dipole substantially along the central axis of the paraboloid, that nearly all light emitted by the dipole is collimated, by total internal reflection from the high index/low index interface. Through correct orientation of the dipole the directions in which the geometry of the system prevents total internal reflection occurring can be made to coincide with those directions where the dipole does not efficiently emit, thus minimising losses.

In an embodiment, the above component comprises a quantum emitter located at the focal point of a paraboloid fashioned from a high refractive index material and surrounded by a lower refractive index material, with said single emitter orientated with its dipole axis along the direction of the axis of said symmetric elliptic paraboloid.

In addition, the utility of embodiments is not dependent on the wavelength of emission as the refractive index of these materials varies slowly with wavelength. This may be advantageous for light sources that emit light over a range of wavelengths (such as nitrogen vacancy centers in diamond at room temperature) or quantum dots emitting entangled photon pairs, where each photon of the pair is typically separated in energy by a few milli-eV. In this case the two dipole axes of the dot (parallel to the polarisations of fine-structure split exciton eigenstates) are arranged at 45 degrees to the axis of the paraboloid to ensure they are both equally, and efficiently collected.

The reflector may also be fabricated from diamond, in which case the paraboloid can be machined using a “Focussed Ion Beam” (for example Gallium ions accelerated to an energy of 30 keV) which it is known can be used to machine 3-D shapes in diamond, with sub-micron resolution. The high energy Ga ions “mill” away the diamond in a controlled fashion. It is standard practise to use low energy ions or electron microscopy to image the progress of this milling action in the same FIB system. Thus as the shaping of the reflector progresses, adjustments can be made allowing accurate formation of the desired paraboloidal shape.

Diamond supports a number of optically active defects or colour centers formed by natural occurrence of or controlled implantation of single atoms. These include defects based upon Nitrogen-vacancy centers (which emit at ˜800 nm), Chromium defects (˜750 nm) and nickel defects (˜800 nm) to name a few. In each case single photon emission at room temperature can be achieved provided a single defect can be isolated.

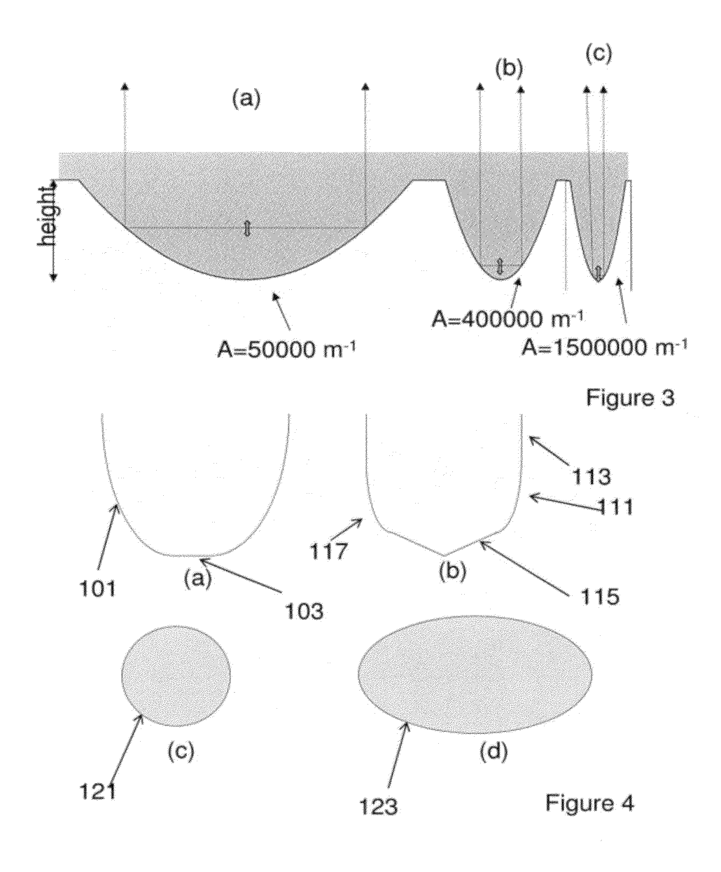

FIG. 3 shows three variations on the paraboloid of FIG. 1. In FIG. 3a the value of parameter A=50000 m⁻¹, meaning that the paraboloid with a height of 10 microns has an outer radius of 14.1 microns, and the dipole must be located at a position 5 microns from the bottom of the paraboloid. In this case the emission pattern has a radius of 10 microns from the center to the radius of highest intensity. However, clearly there is an increased range of upward angles that are not reflected by the paraboloid and thus not collimated.

In FIG. 3b, A=400000 m⁻¹, and FIG. 3c A=1500000 m⁻¹. In FIG. 3c the range of angles that will be reflected is maximised, but the dipole must be located only 167 nm from the bottom of the structure, which may lead to dephasing of the single emitter and also diffraction of the light as it exits the paraboloid—this will reduce the efficiency with which the emission can be collected by a far-field optic of fixed numerical aperture.

The above components have had a reflector which is in the shape of a paraboloid. However, the reflector does not need to be strictly a paraboloid. Any reflector having a paraboloid shaped outer surface should at least partially provide enhanced reflection over non-patterned layers.

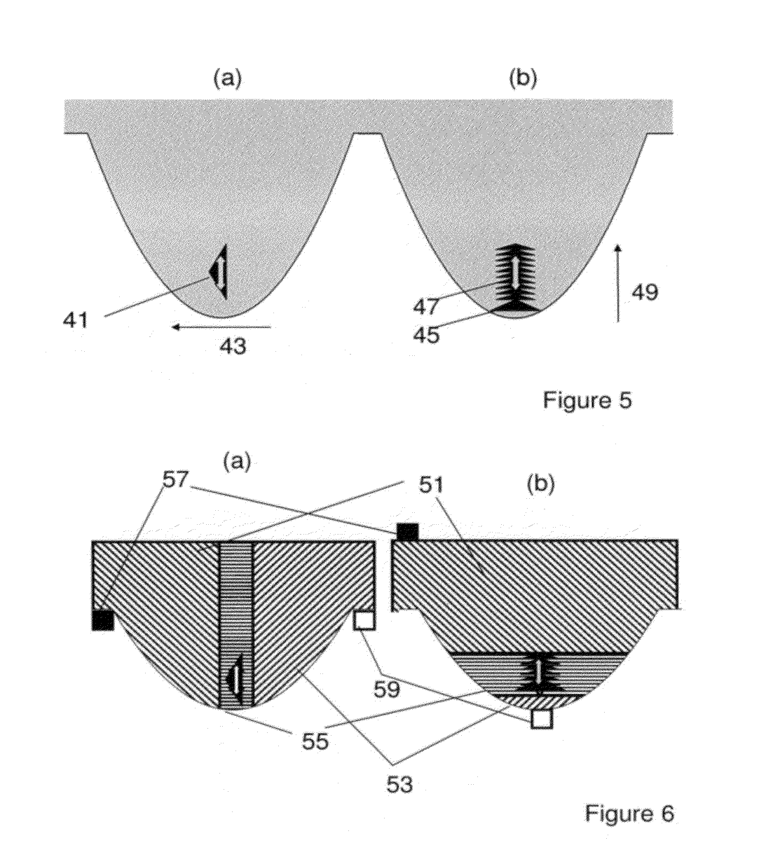

FIG. 4(a) shows a paraboloid reflector 101 in cross section. The paraboloid reflector 101 has a substantially flattened base 103. Although the sides are not strictly a paraboloid, a similar affect will occur to that explained with reference to FIG. 2.

FIG. 4(b) shows a further variation of the type of reflector 111. The reflector 111 has straight line sides 113 at the top and open end of the reflector and straight line sides at the lower end of the reflector 115. The middle section 117 has a paraboloidal profile. This will work in a similar manner as described with reference to the pure paraboloid for a quantum dot provided at the focus of the partial paraboloidal shape 117.

Variations on the paraboloidal shape may happen during processing. The paraboloid may become elongated or possibly there may be a flattening of some of the curves. FIG. 4(c) shows a plan view of the paraboloid of FIG. 1. The plan view of the paraboloid 121 is circular. However, during processing, it is possible that the paraboloid may become elongated in one or more directions and in such a case, the paraboloid will have a more elliptical cross section 123 as shown in FIG. 4(d).

Where the paraboloid has more elliptical cross section, there may not be a central axis of rotational symmetry. However, there will always be a central axis flowing from the apex or centre of the paraboloid through to the open end of the paraboloid or parabola.

It is also possible that due to variations in processing, the dipole axis may not be perfectly aligned with the central axis of the paraboloid. Some misalignment, up to 45° will still allow the paraboloid to reflect a reasonable amount of the photons emitted by the quantum dot.

FIG. 5(a) shows device in accordance with an embodiment, comprising an undoped GaAs reflector, with a QD 41 optically excited at the focal point of the reflector in this embodiment, the reflector 40 is a paraboloid. The quantum dot 41 is formed of InAs. In one embodiment, this quantum dot is formed by self-assembly of InAs when deposited onto the [001] facet of a GaAs wafer, provided greater than 1.8 monolayers of InAs is deposited. Naturally this dot forms with a flat-shape (typically 4-5 nm in height and 10-30 nm in width), the cross-section of the dot being shown here as a pyramid. In this case the optical dipole is at right angles to the growth direction 43, and is overlaid with GaAs. Thus to create the paraboloid reflector the wafer must be rotated though ninety degrees before defining the paraboloid, as will be discussed later.

FIG. 5(b) shows a device in accordance with a further embodiment with a GaAs paraboloid and a “sub-monolayer” quantum dot. This quantum dot is formed from a larger single self assembled dot 45 initially deposited consisting of >1.8 monolayers of GaAs and then over laid with repeated depositions of alternating layers of GaAs (typically 1.0 to 3.0 ML of GaAs and 0.5-1.0 ML of InAs). Under such conditions the InAs layers naturally self-assemble into a sub-monolayer stack, aligned to the first quantum dot 45. The stack is then finally capped with GaAs. Thus forming a “sub-monolayer quantum dot” which is of greater height than width, and having its optical dipole parallel to the growth direction 49.

In the embodiments of FIGS. 5(a) and 5(b), a quantum dot is located at the focal point of a paraboloid fashioned from a high refractive index undoped semiconductor material and surrounded by a lower refractive index material, such as air, with said single quantum dot configured to have its optical dipole along the direction of the axis of said paraboloid. The quantum dot would be excited by a laser focussed to excite the optical dipole, and emission would occur into the substrate where it would exit the semiconductor through an anti-reflection coating.

FIG. 6(a) shows a component in accordance with a further embodiment. The reflector 50 comprises doped GaAs formed into a p-i-n diode, with a single self-assembled dot electrically excited at the focal point of the paraboloid. In this embodiment, the quantum dot is electrically excited.

In a component of FIG. 6a, the quantum dot is located in undoped GaAs region 55. undoped gallium arsenide region 55 is located at the centre of paraboloid reflector 50. And forms a slice through the centre of the reflector 50. On one side of the undoped region 55 is p-doped region 53. On the other side of the and doped region to the p-doped region is n-doped region 55. A p-type contact 59 is made to the p-doped region 53 and then n-type contact 57 is made to the n-doped region 55. This allows a field to be applied across the n doped region 61 which contains the quantum dot.

The structure of FIG. 6 may be formed by forming a layer of p-type material 53 then undoped layer 55 which contains the quantum dot 41 and finally and n-type doped layer 55 is provided. The structure is then a patent on its edge to form a paraboloid reflector 50. Once the paraboloid reflector is formed, the p-type 59 and n-type 57 contacts are formed.

FIG. 6(b) shows a component in accordance with an embodiment comprising doped GaAs formed into a p-i-n diode, with a single “sub-monolayer” dot electrically excited at the focal point of the paraboloid.

In the structure shown in FIG. 6(b), the quantum dot is provided as a sub-monolayer quantum dot. Such quantum dot forms with the dipole aligned in the direction of growth. Therefore, in this type quantum dot, the layer structure is rotated by 90° to that explained with reference to FIG. 6(a). In FIG. 6(b), P-type region 53 is formed at the base of the paraboloid 50. Next, a plurality of layers are formed with quantum dot 47 which allows quantum dot to be formed with its dipole aligned with the direction of growth as explained with reference to FIG. 5(b). Overlying and in contact with a plurality of undoped layers 55 is n-doped region 51 which forms the top of the paraboloid 50.

The structure is then etched to form paraboloid 50 and then n-type contact 57 is made to n-type region 51 and p-type contact 59 is made to p-type region 53.

In the embodiments of FIGS. 6(a) and 6(b), a quantum dot is located at the focal point of a paraboloid fashioned from a high refractive index semiconductor material and surrounded by a lower refractive index material, such as air, with said single quantum dot configured to have its optical dipole axis along the direction of the axis of said paraboloid. The semiconductor would be a doped p-i-n structure with ohmic electrical contacts on either side of the paraboloid, each injecting either charge carriers to the intrinsic region of the diode. A single quantum dot located in the intrinsic region would be thus electrically excited, emitting photons which are collimated by said paraboloid reflector, into the substrate where it would exit the semiconductor through an anti-reflection coating.

Where the dipole is formed in the plane of a semiconductor layer; processing must be carried out on the edge semiconductor wafer.

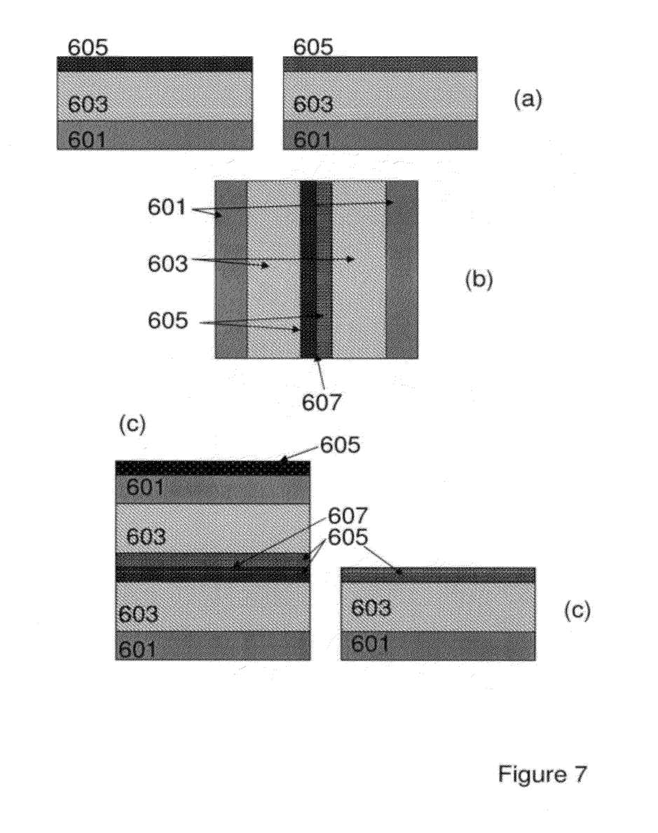

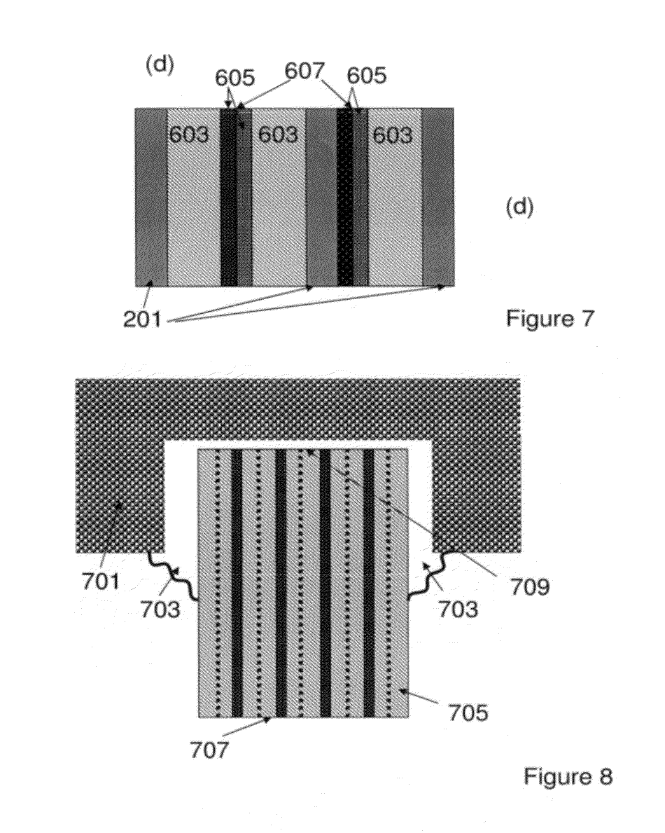

A method in accordance with an embodiment of the present invention will be described with reference to FIGS. 7(a) to 7(d). To aid fabrication where patterning is required at the edge of the wafer, a plurality of wafers are bonded together.

The bonding procedure involves compression of the samples at high temperature using a bonding layer. The procedure used in a method in accordance with an embodiment of the present invention is as follows:

the wafer is cleaved into samples of the approximate dimensions of 3 mm×20 mm bonding procedure consists of several stages where in each stage a sample is bonded to the stack of the already bonded samples.
the cleanliness of the sample surface is important: each defect on the sample surface may result in weaker bond.

FIG. 7(a) to (d) show some of the stages in bonding wafers in accordance with this method. Substrate 601 is provided. In this example, the substrate 601 is undoped. Next, a semiconductor structure 603 is formed. To form the structure shown in FIG. 6(a), first, a p-type region is grown, followed by an undoped region in which is formed a quantum dot and then an n-type region is formed overlying the undoped region. In an embodiment, the semiconductor structure 603 will be epitaxially grown.

The wafer is then divided into smaller samples. Two samples are shown in FIG. 7(a). Titanium/Gold (Ti/Au) 605 is thermally evaporated on the surface of the semiconductor structure 603. The thickness of Ti adhesion layer is typically 10 nm and of Au bonding layer 250 nm. Other alternative metals can be used for wafer bonding i.e. Ti/Cr/Pd for adhesion and Ag/Al for bonding. The smoother the evaporated layer 605, the better the bonding quality.

The samples with metal layer deposited are then placed in a jig: metal layers facing each other as shown in FIG. 7(b). The jig is clamped so that the samples inside are squeezed against each other. The jig is ten left for at least an hour at 400° C. followed by a gentle cool down. At this stage the metal-metal interface 607 is formed and the samples are bonded. In order to improve the quality of the bond a rapid thermo-annealing is used (3-5 min at top temperature of 450° C.).

Next the surface of the stacked samples is metalized as shown in FIG. 7(c). In this embodiment, the metallisation is the same as that used previously i.e. Ti/Au.

A jig is used to bond the next sample onto a stack of the already bonded samples as shown in FIG. 6(d).

The samples were then continually bonded until a laminated structure with a sufficient edge width is built up. This method allows bonding of n number of samples.

The sample edge must now be polished, which is described with reference to FIG. 8. The paraboloids are fabricated on the edge 707 of the laminated sample therefore it is critical to provide good quality edges of the samples. This is difficult to achieve relying only on accurate sample cleaving and bonding therefore mechanical polishing of the edges of the bonded samples is recommended.

The bonded stack of samples is placed in a stab 701 and mounted with an adhesive 703 that can be dissolved using solvent that would not influence the bonded stack.

The mounting method is presented in FIG. 8. A special design of a stab 701 with a mechanism supporting the stack from each side is desirable. The stacked samples 705 are mounted to the stab 701 using adhesive 703 so that the wafer growth direction is perpendicular to the surface of the stab. The edge 707 of the mounted sample stack is polished. The same polishing procedure is applied to the opposite edge 709 of the stacked samples. At the end the stack is released from the stab and cleaned.

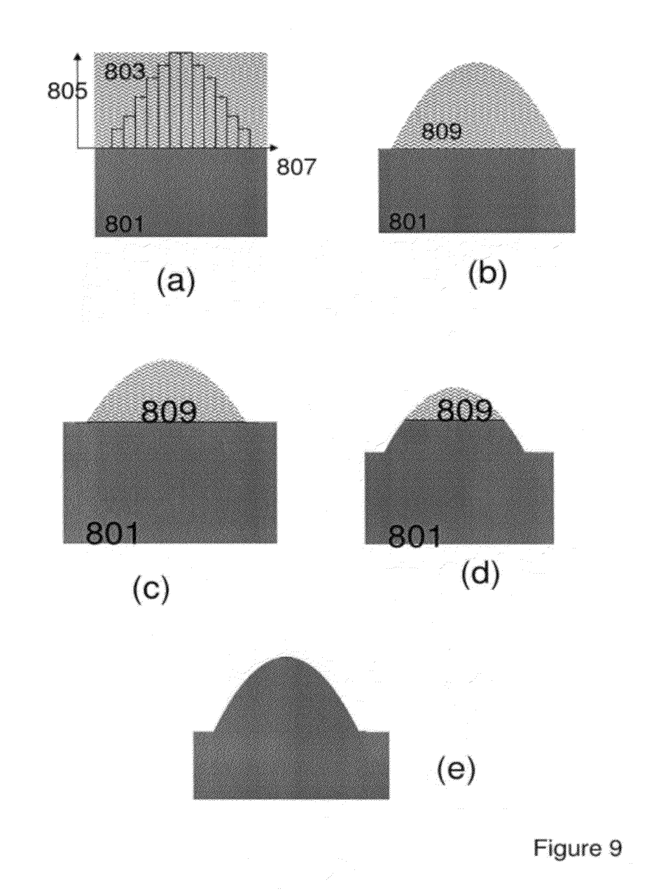

With reference to FIGS. 8 and 9, the pattern is defined in electron beam lithography resist spun on the polished edge 707 of the stack bonded samples. The bigger the area of the edge of the stack bonded sample the more uniformly resist can be spun. Before spinning the resist the stack bonded samples are mounted on a glass slide for easy handling. The electron beam resist applied can be one of the following: PMMA, UVN30, MA-N24x.

The 3D pattern of paraboloids is defined in a resist using grey-scale electron beam lithography. A good quality grey-scale electron beam lithography can be achieved using ultra high resolution electron beam lithography systems like i.e. Leica VB6 UHR. The parameters during pattern definition are: beam step size, write field and electron beam dose. Precise electron beam dose applied with a small step size results with overdosing/underdosing of the paraboloid area that leads to 3D features in the pattern after development.

The main principle of the grey scale lithography is presented in FIGS. 9(a) and 9(b). By irradiating the resist 803 spun on a substrate 801 with electron beam of various doses 805 a grey scale pattern can be defined along the surface of the substrate 807. This will correspond to different thicknesses of the resist after development as shown in FIG. 9b.

With reference to FIGS. 9(c) and 9(d), the 3D shape of the paraboloid is transferred to the semiconductor by means of precisely controlled dry etching. A fixed ratio of etch rates between resist and semiconductor will result in a faithful transfer of the shape into the semiconductor, with elongation of the paraboloid along its axis for fast semiconductor etch rates. In case of III-V semiconductors Si₃Cl₄ or SF₆ based process can be applied. The important factors here are: the uniformity of the etch, etch process based on physical etch mode rather than chemical and negligible polymer re-deposition. The main principle of the pattern transfer is presented in FIG. 9(e) where the 3D pattern defined in resist 809 is gradually etched into the substrate 801.

It is likely that the transferred 3D pattern has rough surface which results from poor e-beam resolution and etching. In an embodiment, to improve the surface quality an oxidation in oxygen plasma is applied. The gallium/arsenic oxide formed is later removed selectively in 5% HCl:H₂0 or 10% C₆H₈O₇:H₂0.

FIGS. 7 to 9 describe the processing of the type structures shown in FIGS. 5(a) and 6(a), with the dipole is formed perpendicular to the growth direction of the samples and hence it is necessary to process the samples on their edges. However, FIGS. 5(b) and 6b showed structures with the dipole was formed parallel to the growth direction. These type of structures would not require the parabola or paraboloid to be etched on the edges of the structures and therefore would not require the wafer bonding techniques described with reference to FIGS. 7 and 8. However, they could use the greyscale lithography described with reference to FIG. 9 to define the shape of the paraboloid or parabola.

In a further embodiment, the component comprises a single colour center located at the focal point of a paraboloid fashioned from diamond and surrounded by a lower refractive index material, such as air, with said single colour center orientated with its dipole axis along the direction of the axis of said paraboloid.

While certain embodiments have been described, these embodiments have been presented by way of example only, and are not intended to limit the scope of the inventions. Indeed, the novel components and methods described herein may be embodied in a variety of other forms; furthermore, various omissions, substitutions and changes in the form of the component and methods described herein may be made without departing from the spirit of the inventions. The accompanying claims and their equivalents are intended to cover such forms or modifications as would fall within the scope and spirit of the inventions.

1. An optical component comprising an emitter and a solid reflector, said reflector having a convex outer surface, said emitter being located within the solid reflector, the emitter being configured to emit radiation via an electric dipole transition, the dipole having a dipole axis being orientated at an angle of 45 degrees or less to the surface normal at the apex of the reflector.

2. An optical component according to claim 1, wherein the apex is the point of the convex outer surface which is closest to the emitter.

3. An optical component according to claim 1, wherein said reflector has a paraboloid-shaped outer surface and a central axis extending from the apex of the paraboloid along the normal to the surface at this apex.

4. An optical component according to claim 3, wherein said emitter is provided at the focus of the paraboloid.

5. An optical component according to claim 1, wherein said dipole is positioned such that at least 50% of its emission is reflected by the outer surface in a direction parallel to the surface normal at the apex of the reflector.

6. An optical component according to claim 1, wherein the outer surface of said solid reflector has a shape defined by the equation in cylindrical polar coordinates:
z=Ar^{2α}
where z is the distance along the axis of rotational symmetry, r is the distance from the axis of rotational symmetry and a is a number between 0.95 and 1.05.

7. An optical component according to claim 6, wherein α=1

8. An optical component according to claim 1, wherein at least a part of the reflector has a focal point within the solid reflector and the emitter is located at said focal point.

9. An optical component according to claim 1, further comprising a laser configured to optically excite said emitter.

10. An optical component according to claim 1, further comprising electrical contacts configured to electrically excite said emitter.

11. An optical component according to claim 1, wherein said emitter comprises a quantum dot and said solid reflector comprises a semiconductor based material.

12. An optical component according to claim 1, wherein said solid reflector comprises diamond and said emitter comprises a defect or colour centre in said diamond.

13. An optical component according to claim 1, wherein a surrounding material is air.

14. An optical component according to claim 1, where the surrounding material has a refractive index below that of the solid reflector.

15. An optical component according to claim 1, where the reflector is coated with metal.

16. A method of forming an optical component, the method comprising:
forming a quantum dot provided within a solid structure, said quantum dot having a dipole axis;
patterning said solid structure to have a shape which is substantially a paraboloid,
the solid structure having a central axis extending from the apex of the paraboloid and through the centre of the paraboloid, said patterning positioning said solid structure such that the dipole axis of said quantum dot forms an angle of 45 degrees or less with the central axis of the reflector, the reflector having a refractive index which is higher than any surrounding medium.

17. A method according to claim 16, wherein patterning said structure comprises providing a grey-scale resist to define said paraboloid shape.

18. A method according to claim 16, wherein patterning said structure comprises defining said paraboloid shape using a focussed ion beam.

19. A method according to claim 17, wherein a plurality of wafer pieces are produced with quantum dots and said wafer pieces are wafer bonded together for patterning.

20. A method according to claim 16, wherein said quantum dot is formed using a self-assembled technique.
